(19) United States
(12) Patent Application Publication
(10) Pub. No.: US 2013/0287947 A1
(43) Pub. Date: Oct. 31, 2013

(54) Inverted Evaporation Apparatus

(71) Applicant: AREESYS CORPORATION, Fremont, CA (US)

(72) Inventors: Kai-An Wang, Cupertino, CA (US); Albert Ting, San Jose, CA (US); Enhao Lin, Fremont, CA (US); Michael Wong, Castro Valley, CA (US)

(73) Assignee: AREESYS CORPORATION, Fremont, CA (US)

(21) Appl. No.: 13/854,838

(22) Filed: Apr. 1, 2013

Related U.S. Application Data
(60) Provisional application No. 61/639,674, filed on Apr. 27, 2012.

(51) Int. Cl. C23C 16/448

(52) U.S. Cl. CPC C23C 16/4485
USPC 427/248.1; 118/725

(57) ABSTRACT

A deposition apparatus includes one or more evaporation sources each of which includes a container comprising an opening and configured to hold a source material, a source heater adjacent to and in thermal communication with the container, wherein the source heater is configured to elevate temperature of the source material to produce a vapor of the source material, and a source enclosure that encloses the container and the source heater. The source enclosure includes a vent configured to direct the vapor of the source material towards a substrate. The deposition apparatus includes also a plurality of substrate heaters in thermal communication with the substrate. The substrate includes a deposition surface configured to receive deposition of the source material by condensing the vapor. The plurality of substrate heaters can heat different portions of the substrate to different temperatures.

### BACKGROUND OF THE INVENTION

The present application relates to material deposition technologies, and more specifically to evaporation deposition systems.

A conventional evaporation deposition system 100, referring to FIG. 1, includes a vacuum chamber 105 that can be evacuated by a pump system 107. A substrate 110 is positioned at the top. One or more evaporation sources 120 are positioned at the bottom. Vapors are produced at evaporation sources 120, and rise to the top. The evaporation sources 120, for example, can contain Sn and S source materials. Each source material can be heated by a heating element 125 (often also acting as a crucible or material loading “boat”) to generate vapor that moves upward. A PID (proportional-integral-derivative) controller 115 is used to control a substrate heater 117, which is placed above the substrate 110. The PID controller is used because it is considered to have better control accuracy and faster response than most simple temperature controllers. To monitor the thickness of the film being deposited, a quartz sensor 130 is placed on the side of the substrate and can collect vapor flux coming from the evaporation sources 120. A thickness monitor 135 is used to control and to read thickness signal from the quartz sensor 130.

One challenge facing deposition of evaporated source material is that it is difficult to ensure uniform deposition on the substrate, especially on large substrates. Another challenge associated with the conventional system is that the substrate often softens and sags when is heated during deposition. In a conventional system, there is little or no accurate control of the temperature gradient or temperature field inside the crucible or boat. It is also difficult to achieve high materials utilization while minimizing wasted material deposition on chamber walls.

### SUMMARY OF THE INVENTION

The presently disclosed deposition apparatus can minimize deformation of substrate especially at high process temperatures, simplify the substrate transport mechanism, and provide refined control of the vapor flux. The disclosed deposition apparatus can improve deposition uniformity, increase materials utilization, maximize deposition on the substrate, and minimize deposition on chamber walls. The disclosed apparatus has much improved fine control of the temperature field or profile inside the crucible or boat which is a much needed feature to avoid material “spitting” and hence eliminating defects such as pin holes in deposited films. The disclosed apparatus is compatible with planar rigid substrates or flexible substrates, and different substrate positions: top, bottom, side, or skewed. The disclosed apparatus also has increased energy efficiency in the heating system and improves controllability of temperature.

In one general aspect, the present invention relates to a deposition apparatus that includes one or more evaporation sources each comprising: a container comprising an opening and configured to hold a source material; a first source heater adjacent to and in thermal communication with the container, wherein the first source heater is configured to elevate temperature of the source material to produce a vapor of the source material; and a source enclosure that encloses the container and the first source heater, wherein the source enclosure comprises a vent configured to direct the vapor of the source material towards a substrate. The deposition apparatus includes a plurality of first substrate heaters in thermal communication with the substrate, wherein the substrate comprises a deposition surface configured to receive deposition of the source material by condensing the vapor, wherein the plurality of substrate heaters are configured to heat different portions of the substrate to different temperatures.

Implementations of the system may include one or more of the following. The substrate can be positioned below the evaporation source, wherein the deposition surface of the substrate is facing upward, wherein the vent in the source enclosure is substantially facing downward. The first source heater can be positioned under the container. The first substrate heaters can be positioned under the substrate. The deposition apparatus can further include one or more second substrate heaters surrounding a space between the source enclosure and the substrate, wherein one or more second substrate heaters are configured to provide temperature uniformity across the substrate. The deposition apparatus can further include a second source heater positioned adjacent to the opening of the container, wherein the second source heater is configured to increase vapor pressure near the opening to prevent spitting of the source material from the container. The source enclosure can include one or more closed walls, wherein the container comprises an open side facing one of the closed walls opposite to the vent in the source enclosure. One or more closed walls of the source enclosure and the container can define one or more flow paths to guide the vapor to flow from the opening of the container to the vent in the source enclosure. The first source heater can be positioned on the side of the container facing the vent in the source enclosure. The deposition surface of the substrate can be positioned substantially vertical, wherein the vent in the source enclosure is substantially facing along a horizontal direction towards the deposition surface. The first source heater can be positioned under the container. The first substrate heaters can be positioned on the side of the substrate opposite to the source enclosure. The deposition apparatus can further include a transport mechanism configured to produce a relative movement between the substrate and one or more evaporation sources to allow the source material to be deposited across different portions of the deposition surface.

In another general aspect, the present invention relates to a method of material deposition. The method includes holding a source material in a container enclosed in an evaporation source, wherein the container comprises an opening; heating the source material in the container by a first source heater to produce a vapor of the source material; guiding the vapor from the container to a vent in the source enclosure; directing the vapor of the source material towards a substrate; heating different portions of the substrate to different temperatures by a plurality of first substrate heaters in thermal communication with the substrate; and depositing the source material onto the substrate by condensing the vapor on the substrate.

Implementations of the system may include one or more of the following. The substrate can be positioned below the evaporation source, wherein the deposition surface of the substrate is facing upward, and the method can further include directing the vapor of the source material downward towards the deposition surface. The deposition surface of the substrate can be positioned substantially vertical, wherein the vent in the source enclosure is substantially facing a horizontal direction towards the deposition surface, and the method can further include directing the vapor of the source material sideways towards the deposition surface. The method can further include controlling temperatures of the substrate and the vent in the source enclosure; and keeping temperature of the substrate lower than temperature of the source enclosure to prevent deposition on the vent in the source enclosure. The method can further include heating a space between the source enclosure and the substrate by one or more second substrate heaters surrounding the space to provide temperature uniformity across the substrate. The method can further include keeping temperature near the opening of the container higher than temperature of the source material in the container by a second source heater; and increasing vapor pressure near the opening of the container to prevent spitting of the source material from the container. The method can further include producing a temperature distribution in the substrate, wherein the temperature distribution is characterized by an increase in temperature in an area of the substrate with an increases in the distance from the area of the substrate to the vent of the deposition source. The method can further include producing a relative movement between the substrate and one or more evaporation sources to allow the source material to be deposited across different portions of the deposition surface.

These and other aspects, their implementations and other features are described in detail in the drawings, the description and the claims.

### BRIEF DESCRIPTION OF THE DRAWINGS

FIG. 1 shows an exemplified conventional evaporation deposition system.

FIG. 2 is a perspective view of an evaporation deposition system in accordance with the present invention.

FIG. 3 is a perspective view of the evaporation deposition system of FIG. 2 without chamber walls.

FIG. 4 is a perspective view of the evaporation source in the evaporation deposition system of FIG. 2.

FIG. 5 is a cross-sectional view of multiple evaporation sources and a substrate in the evaporation deposition system of FIG. 2.

FIG. 6A illustrates evaporation sources that can be moved across a stationary substrate in accordance with the present invention.

FIG. 6B illustrates a substrate that can be moved under stationary evaporation sources in accordance with the present invention.

FIG. 7A is a perspective view of an evaporation deposition system including multiple evaporation sources and a substrate arranged in a vertical position in accordance with the present invention.

FIG. 7B is a detailed view of components inside an evaporation source that is compatible with the vertical arrangement.

FIG. 8 shows a flowchart for the evaporation deposition system in accordance with the present invention.

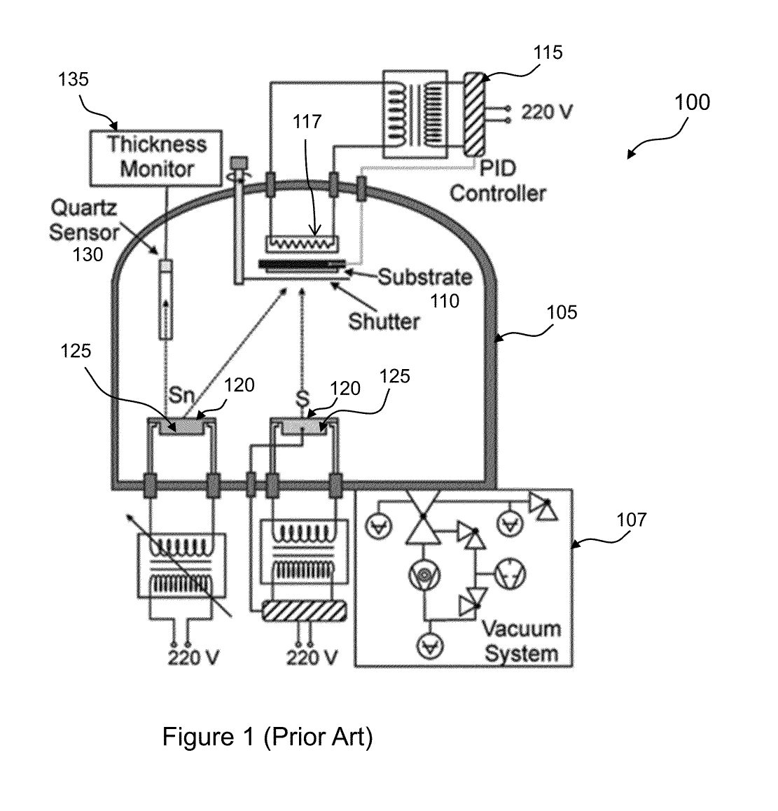

### DETAILED DESCRIPTION OF THE INVENTION

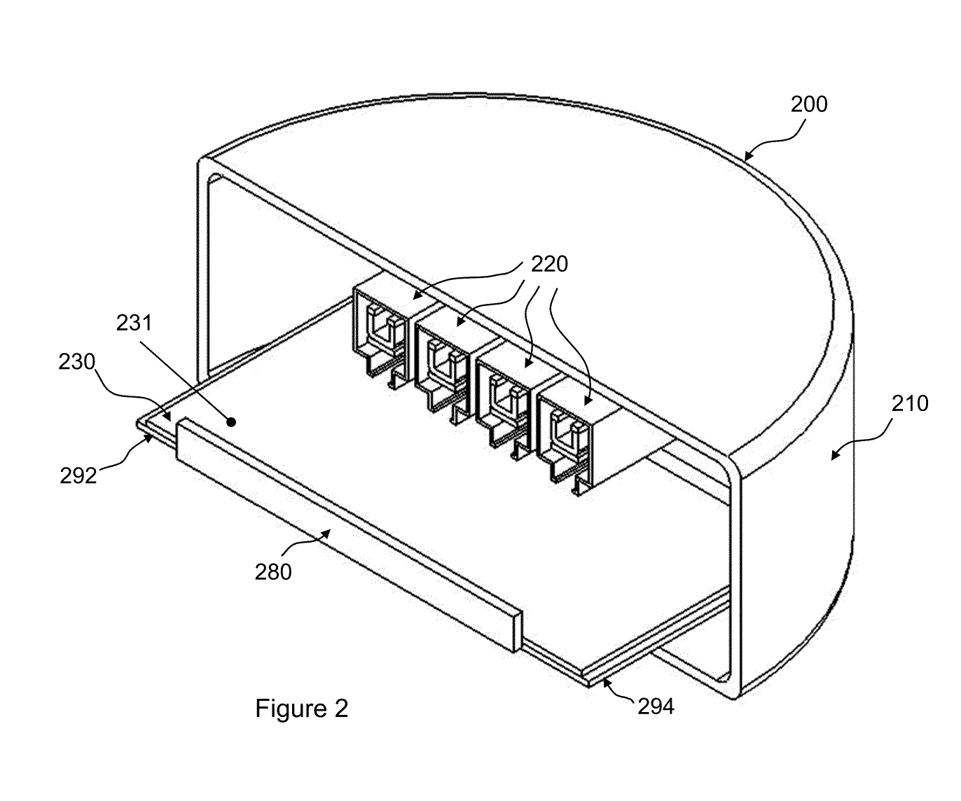

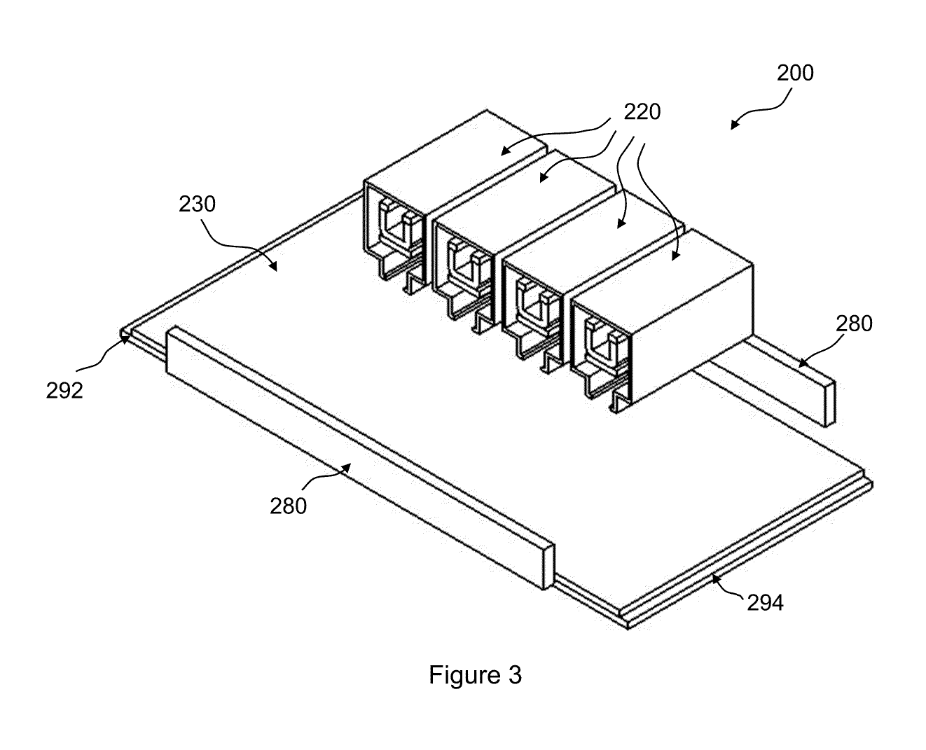

In some embodiments, referring to FIGS. 2-4, an inverted evaporation apparatus 200 includes a vacuum chamber 210, one or more inverted evaporation sources 220 positioned inside the vacuum chamber 210, and a substrate 230 positioned below one or more inverted evaporation sources 220. Each inverted evaporation source 220 can produce vapor flux that is channeled from the top to the bottom towards the substrate 230 to allow the vapor to condense onto the substrate 230 and deposit the source material onto the substrate 230.

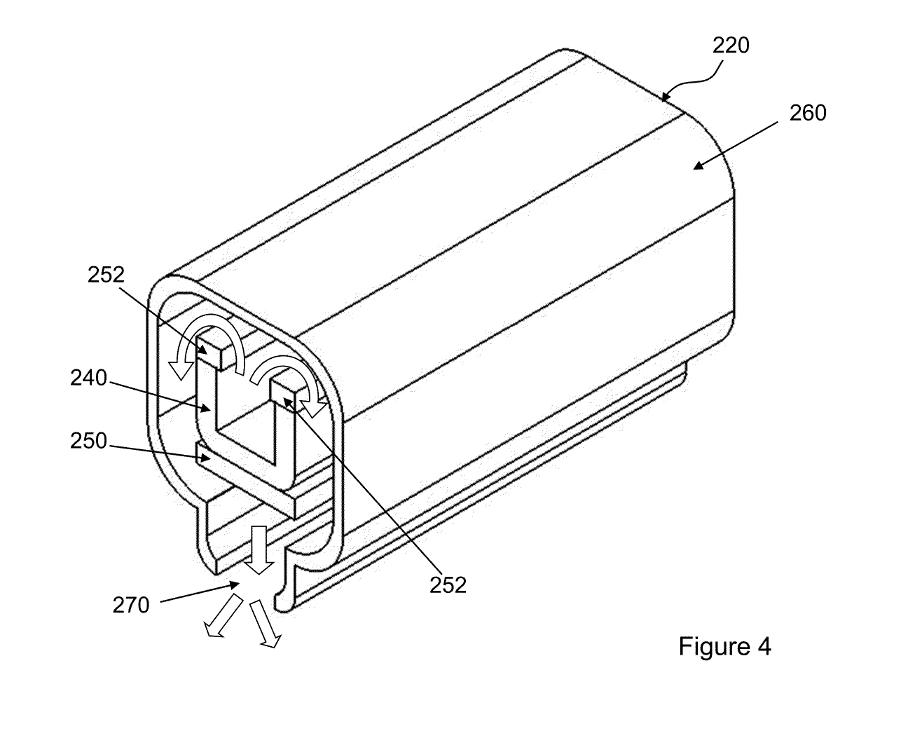

The inverted evaporation source 220 includes a boat 240 (i.e. a container with opening) for containing a source material and one or more heaters 250, 252 configured to heat and vaporize the source material. The source material and one or more heaters are enclosed in a source enclosure 260 with a vent 270 at the bottom. The source enclosure 260 includes one or more closed walls which, together with boat 240, defines flow path(s) (as indicated by the wide arrows in FIG. 4) to direct the vapor towards and exit the vent 270 and subsequently towards the substrate 230 underneath. The source enclosure 260 is heated to minimize vapor condensation on walls of the source enclosure 260. The source heater 250 is positioned below the boat 240. One or more source heaters 252 are positioned along the upper edge around the opening of the boat 240.

In most applications with the disclosed apparatus, it is important that the source heaters 252 are kept at higher temperature than the temperature of the source heater 250 to prevent “spitting” or uncontrolled sudden eruption of the evaporation material. In contrast, in conventional evaporation sources, usually there is only one heater to heat the boat which often results in higher temperature close to the bottom of the boat (or crucible) than close to the top. The materials exposed to uneven temperatures inside the boat would have higher vapor pressures near the bottom than near the top. The imbalance in vapor pressure tends to cause ‘spitting” of the materials, which should be otherwise evaporated gently from the boat. “Spitting” is a direct root cause responsible for particulates and pin holes in deposited films. In the disclosed deposition apparatus, the heaters 252 are configured to increase vapor pressure near the edge or rim of the container 240 to counter balance the high vapor pressure near the bottom of the container 240, which eliminates or reduces the driving force for “spitting”. The two-heater design of the disclosed evaporation source and independent controls of the two heaters in this invention effectively prevent “spitting” from happening.

In the disclosed apparatus, the heaters 280, 290, 292 and 294 are carefully arranged and controlled to fine tune deposition uniformity and improve materials utilization. Referring to FIGS. 2-5, one or more side heaters 280 are positioned surrounding a space between the inverted evaporation source 220 and the substrate 230. The one or more side heaters 280 are on the sides of the substrate 230 and higher than the deposition surface 231 of the substrate 230. The one or more side heaters 280 are used to provide temperature uniformity across the substrate 230. Additionally, heaters 290, 292, 294 are positioned under the substrate 230 to maintain an elevated temperature distribution in the substrate 230. The temperature of the substrate 230 is kept lower than the temperature at the vapor vents 270 so that the materials vapor tend to deposit or condense more onto the substrate than onto the vapor vents. Furthermore, the outer areas of the substrate 230 away from immediate vicinity to the vapor vents of the evaporation source or sources are kept at higher temperatures than the area of the substrate 230 in the vicinity to the vapor vent. In other words, heaters 292, 294 are at higher temperature than heater 290.

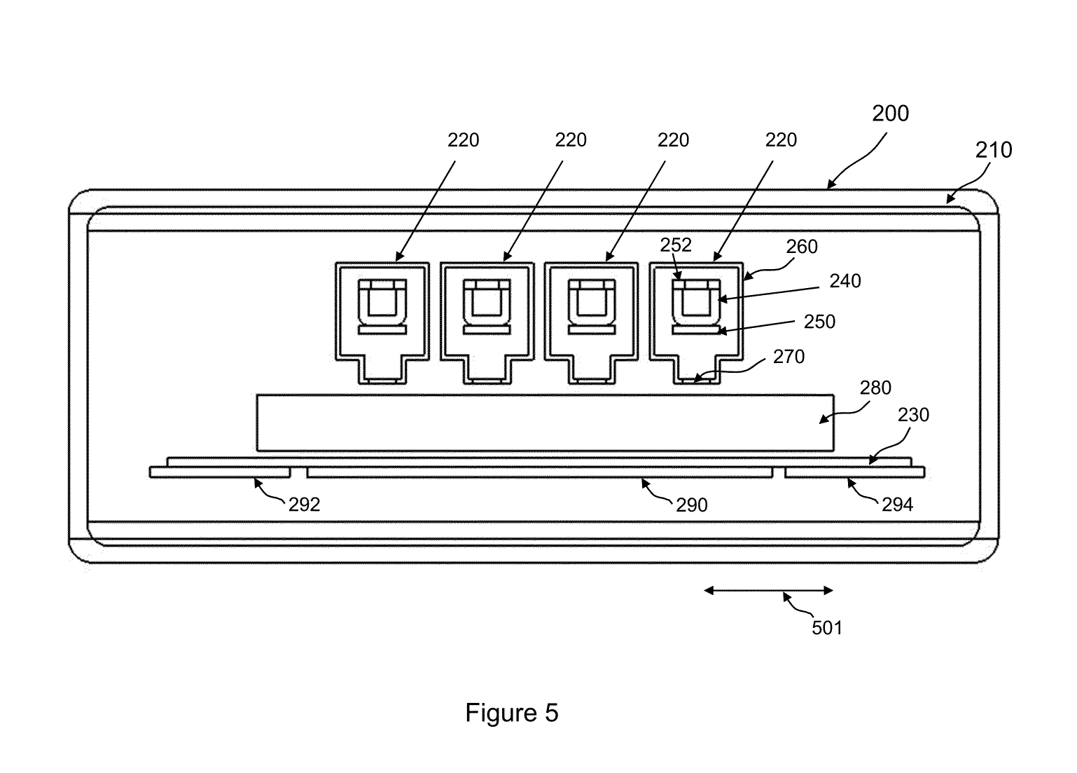

In some embodiments, uniform deposition across the deposition surface of the substrate requires relative movements between the evaporation sources and the substrate. Referring to FIG. 5, the substrate 230 can be moved in the horizontal direction 501 by a transport mechanism (not shown) to provide uniform deposition across the substrate 230.

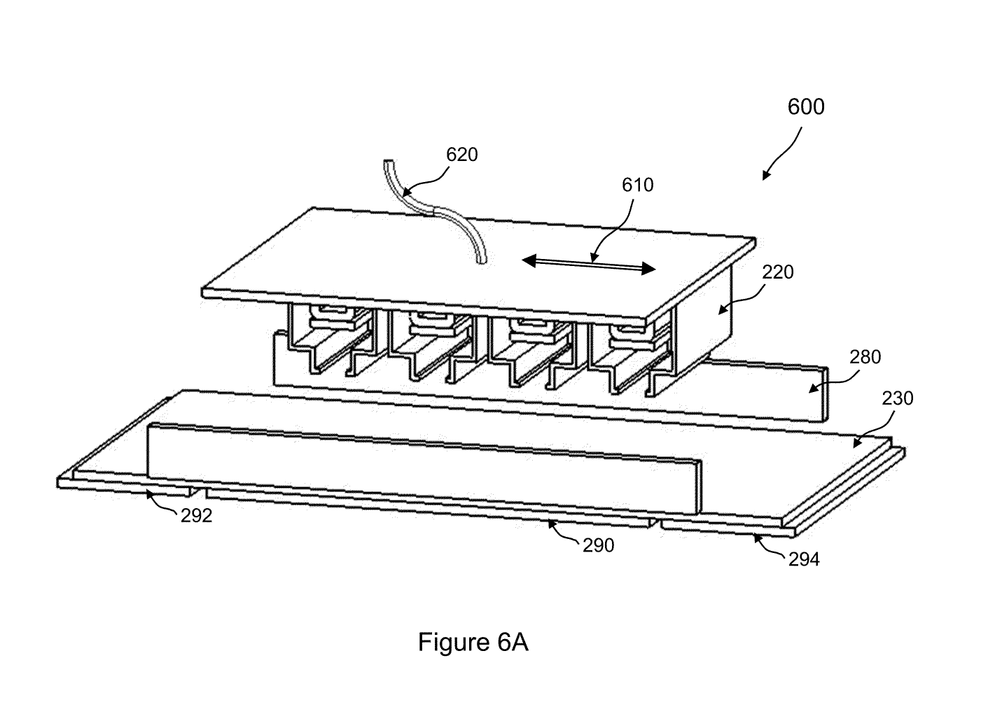

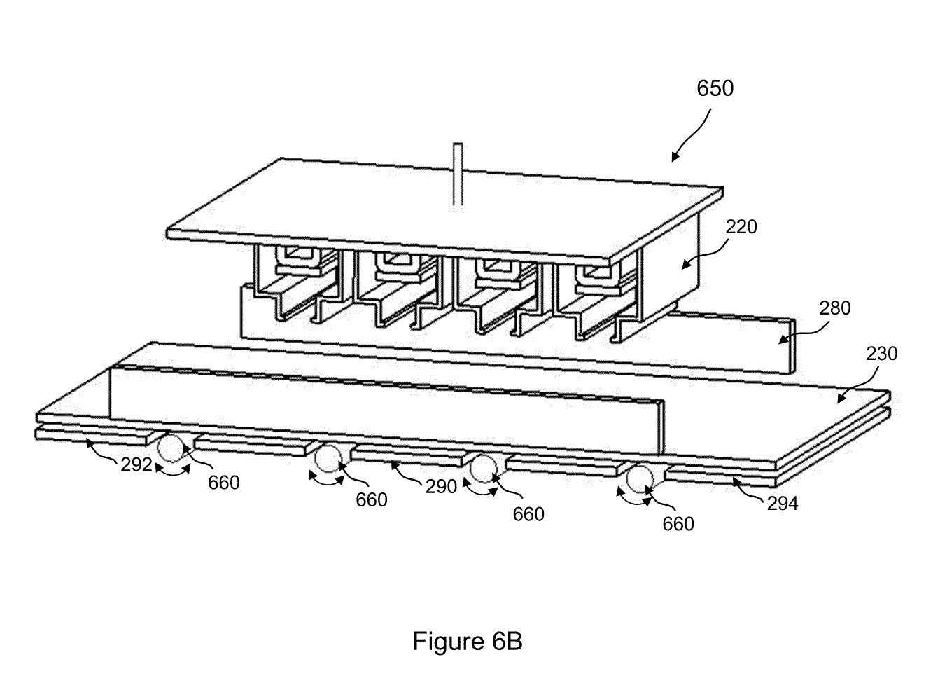

Referring to FIG. 6A, an evaporation deposition system 600 includes evaporation sources 220 that can be moved across a stationary substrate 230. Stationary heaters 280, 290, 292, 294 are positioned adjacent to the substrate 230 to maintain temperature distribution in the substrate 230 as described above. To facilitate the movement of the evaporation sources 220 along direction 610, a flexible electrical cord 620 is connected to the evaporation sources 220 within the vacuum environment in the deposition chamber to provide heating power to the evaporation sources 220.

In a different configuration, referring to FIG. 6B, an evaporation deposition system 650 includes a substrate 230 that can be moved under stationary evaporation sources 220. In one implementation, the heaters 280, 290, 292, 294 can remain stationary while the substrate 230 is moved by a transport mechanism comprising for example rollers 660. The substrate 230 can slide against or over the heaters 290, 292, 294 that remain in thermal communication with each other.

In some embodiments, multiple evaporation sources 220 can be positioned above the substrate 230. The multiple evaporation sources 220 can deposit multiple materials onto the substrate 230 to form layered or stratified thin film stacks, or to form well mixed single material layer.

Placing the substrate 230 below the evaporation sources simplifies the design of the substrate transport mechanism and minimizes the deformation of the substrate during the process when heating to high substrate temperature is needed. For example, when a glass substrate needs to be heated to its softening point during process, it is not practical to use a transport mechanism to hold the glass above an evaporation source without sagging or deforming the glass. The temperatures of heaters 280, 290, 292, 294 can be controlled independently to assure temperature uniformity on the substrate 230 and minimizes deposition on the walls of the vacuum chamber 210.

The design of heaters above and below the substrate provides temperature uniformity on substrate and minimizes deposition on chamber walls.

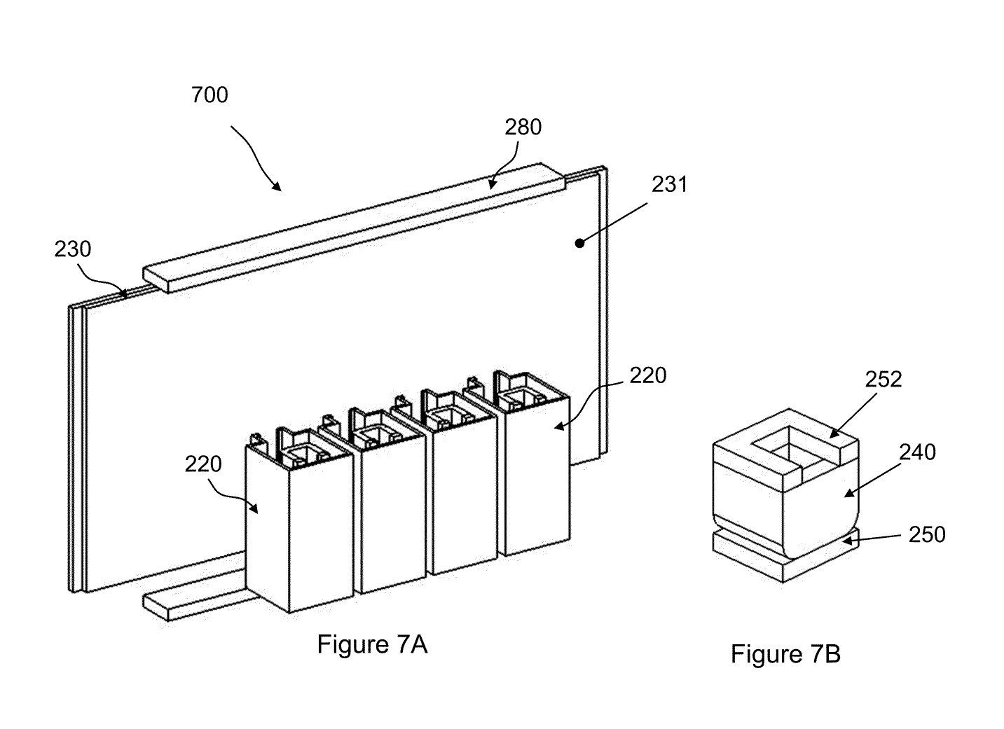

In some embodiments, the substrate may be positioned along a direction other than the horizontal direction; and the evaporation source does not direct the vapor downwards. For example, referring to FIGS. 7A and 7B, an evaporation deposition system 700 includes a planar substrate 230 that is aligned vertically with its deposition surface 231 facing sideways. Evaporation sources 220 are positioned on the side of the substrate 230 which are configured to generate a vapor flux directed horizontally towards the deposition surface 231 of the substrate 230. The evaporation sources 220 can span across the full height dimension of the substrate 230 (Only portions of the evaporation sources 220 are shown in FIG. 7A to reveal the inside of the evaporation sources 220). A boat 240 is configured to hold source material. The heaters 250, 252 configured to heat and vaporize the source material. As described above, in operation, the source heaters 252 are kept at higher temperature than the temperature of the source heater 250 to prevent “spitting”. Multiple boats 240 are arranged in a vertical linear manner in order to extend the length (height) of the evaporation source 220. One advantage of this configuration is that the footprint of the evaporation deposition system may be minimized. Furthermore, the disclosed system can also include evaporation sources generating vapor directing vapor upwards while the deposition surface facing downwards to receive the vapor.

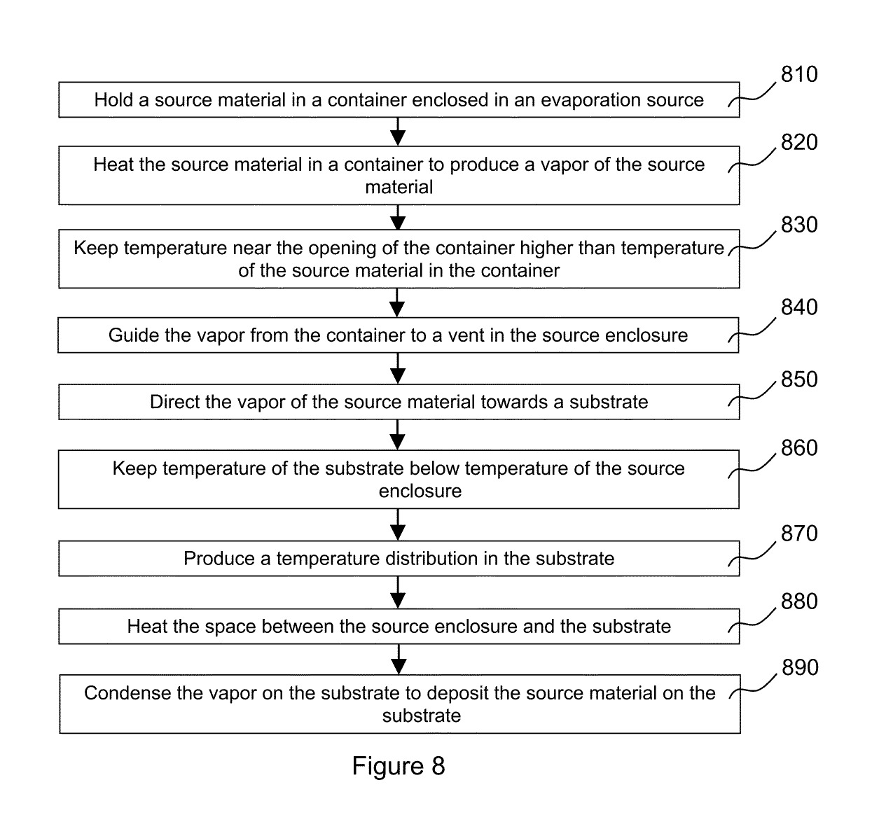

Referring to FIG. 8, the presently disclosed material deposition can include one or more of the following steps: a source material is held in a container enclosed in an evaporation source (step 810). The container comprises an opening. The source material in the container is heated by a first source heater to produce a vapor of the source material (step 820). The temperature near the opening of the container is kept higher than temperature of the source material in the container by a second source heater to increase vapor pressure near the opening of the container to prevent spitting of the source material from the container (step 830). The vapor is guided from the container to a vent in the source enclosure (step 840). The vapor of the source material is directed towards a substrate (step 850). The temperature of the substrate is kept lower than temperature of the source enclosure to prevent deposition on the vent in the source enclosure (step 860). Producing a temperature distribution in the substrate using a plurality of first substrate heaters in thermal communication with the substrate (step 870). The space between the source enclosure and the substrate is heated by one or more second substrate heaters surrounding the space to provide temperature uniformity across the substrate (step 880). The vapor condenses on the substrate and the source material is deposited on the substrate (step 890). Furthermore, a relative movement can be produced between the substrate and one or more evaporation sources to allow the source material to be deposited across different portions of the deposition surface.

Only a few examples and implementations are described. Other implementations, variations, modifications and enhancements to the described examples and implementations may be made without deviating from the spirit of the present invention. For example, the substrate in the disclosed system can also be titled at a smaller-than-90 degree angle with evaporation sources aligned accordingly to direct vapor towards the tilted substrate. The disclosed system can include a computer with controllers that control the temperatures of the heaters and thus the temperature profiles across the substrate and over time.

What is claimed is:

1. A deposition apparatus, comprising:
one or more evaporation sources each comprising:
a container comprising an opening and configured to hold a source material;
a first source heater adjacent to and in thermal communication with the container, wherein the first source heater is configured to elevate temperature of the source material to produce a vapor of the source material; and
a source enclosure that encloses the container and the first source heater, wherein the source enclosure comprises a vent configured to direct the vapor of the source material towards a substrate; and
a plurality of first substrate heaters in thermal communication with the substrate, wherein the substrate comprises a deposition surface configured to receive deposition of the source material by condensing the vapor, wherein the plurality of first substrate heaters are configured to heat different portions of the substrate to different temperatures.

2. The deposition apparatus of claim 1, wherein the substrate is positioned below the evaporation source, wherein the deposition surface of the substrate is facing upward, wherein the vent in the source enclosure is substantially facing downward.

3. The deposition apparatus of claim 2, wherein the first source heater is positioned under the container.

4. The deposition apparatus of claim 2, wherein the first substrate heaters are positioned under the substrate.

5. The deposition apparatus of claim 1, further comprising:
one or more second substrate heaters surrounding a space between the source enclosure and the substrate, wherein the one or more second substrate heaters are configured to provide temperature uniformity across the substrate.

6. The deposition apparatus of claim 1, further comprising:
a second source heater positioned adjacent to the opening of the container, wherein the second source heater is configured to increase vapor pressure near the opening to prevent spitting of the source material from the container.

7. The deposition apparatus of claim 1, wherein the source enclosure includes one or more closed walls, wherein the container comprises an open side facing one of the closed walls opposite to the vent in the source enclosure.

8. The deposition apparatus of claim 7, wherein the one or more closed walls of the source enclosure and the container define one or more flow paths to guide the vapor to flow from the opening of the container to the vent in the source enclosure.

9. The deposition apparatus of claim 7, wherein the first source heater is positioned on the side of the container facing the vent in the source enclosure.

10. The deposition apparatus of claim 1, wherein the deposition surface of the substrate is positioned substantially vertical, wherein the vent in the source enclosure is substantially facing along a horizontal direction towards the deposition surface.

11. The deposition apparatus of claim 10, wherein the first source heater is positioned under the container.

12. The deposition apparatus of claim 10, wherein the first substrate heaters are positioned on the side of the substrate opposite to the source enclosure.

13. The deposition apparatus of claim 1, further comprising:
a transport mechanism configured to produce a relative movement between the substrate and the one or more evaporation sources to allow the source material to be deposited across different portions of the deposition surface.

14. A method of material deposition, comprising:
holding a source material in a container enclosed in an evaporation source, wherein the container comprises an opening;
heating the source material in the container by a first source heater to produce a vapor of the source material;
guiding the vapor from the container to a vent in the source enclosure;
directing the vapor of the source material towards a substrate;
heating different portions of the substrate to different temperatures by a plurality of first substrate heaters in thermal communication with the substrate; and
depositing the source material onto the substrate by condensing the vapor on the substrate.

15. The method of claim 14, wherein the substrate is positioned below the evaporation source, wherein the deposition surface of the substrate is facing upward, the method further comprising:
directing the vapor of the source material downward towards the deposition surface.

16. The method of claim 14, wherein the deposition surface of the substrate is positioned substantially vertical, wherein the vent in the source enclosure is substantially facing a horizontal direction towards the deposition surface, the method further comprising:
directing the vapor of the source material sideways towards the deposition surface.

17. The method of claim 14, further comprising:
controlling temperatures of the substrate and the vent in the source enclosure; and
keeping temperature of the substrate lower than temperature of the source enclosure to prevent deposition on the vent in the source enclosure.

18. The method of claim 14, further comprising:
heating a space between the source enclosure and the substrate by one or more second substrate heaters surrounding the space to provide temperature uniformity across the substrate.

19. The method of claim 1, further comprising:
keeping temperature near the opening of the container higher than temperature of the source material in the container by a second source heater; and
increasing vapor pressure near the opening of the container to prevent spitting of the source material from the container.

20. The method of claim 1, further comprising:
producing a temperature distribution in the substrate, wherein the temperature distribution is characterized by an increase in temperature in an area of the substrate with an increases in the distance from the area of the substrate to the vent of the deposition source.

21. The method of claim 1, further comprising:
producing a relative movement between the substrate and the one or more evaporation sources to allow the source material to be deposited across different portions of the deposition surface.
